(19) United States
(12) Patent Application Publication
(10) Pub. No.: US 2003/0027418 A1
(43) Pub. Date: Feb. 6, 2003

(54) Semiconductor device fabricating method and treating liquid

(75) Inventors: Hidemitsu Aoki, Tokyo (JP); Kenichi Nakabeppu, Tokyo (JP); Hiroaki Tomimori, Tokyo (JP); Toshiyuki Takewaki, Tokyo (JP); Nobuo Hironaga, Tokyo (JP); Hiroyuki Kunishima, Tokyo (JP)

Correspondence Address: McGinn & Gibb, PLLC, Suite 200, 8321 Old Courthouse Road, Vienna, VA, 22182-3817, US

(73) Assignee: NEC Corporation, Tokyo (JP)

(21) Appl. No.: 10/191,531

(22) Filed: Jul. 10, 2002

(30) Foreign Application Priority Data
Jul. 12, 2001 (JP) 212191/2001

(51) Int. Cl. H01L 21/44; H01L 21/4763

(52) U.S. Cl. 438/637; 438/906

(57) ABSTRACT

There are provided a semiconductor device fabricating method for forming a wiring layer on a semiconductor substrate, followed by cleaning, which may prevent elution and oxidation of the wiring layer, and a treating liquid used in the fabricating method. A Cu wiring, an interlayer film over the Cu wiring and an opening in the interlyaer film to expose the surface of the Cu wiring are formed in a plasma atmosphere. IPA is sprayed to the semiconductor device, and then, an organic release process is performed thereto with an amine solvent to remove an etching residue. The semiconductor device is rinsed with the IPA again to remove the remaining amine, and then is cleaned with a treating liquid, which is alkalescent. Then, it is rinsed with pure water or CO₂ water and is dried.

### BACKGROUND OF THE INVENTION

1. Field of the Invention

The present invention relates to a semiconductor device fabricating method including a process for forming a wiring layer, an interlayer film and an opening and a process for cleaning the opening and a treating liquid used in cleaning of the opening. More specifically, the present invention relates to a semiconductor device fabricating method which may prevent elusion and oxidation of the wiring layer in a water rinse process after forming at least one of the interlayer film and the opening under a plasma atmosphere and a treating liquid used in cleaning of the opening. The present application is based on Japanese Application No. 2001-212191, which is incorporated herein by reference.

2. Description of the Related Art

A semiconductor device is fabricated by forming on a semiconductor substrate an interlayer film, a wiring layer made of metal such as Cu, and an opening of the interlayer film by methods such as sputtering, dry etching and plasma ashing. Thereafter, the semiconductor device is cleaned with an organic release liquid to remove contamination such as an etching residue produced when the interlayer film, the wiring layer and the opening are formed. For example, an amine release liquid is used as the organic release liquid.

This will be described by using a flowchart showing a semiconductor device cleaning method with the organic release liquid shown in FIG. 12. FIG. 12 shows a process for forming a via in an interlayer film on a wiring made of Cu (hereinafter, referred to as a Cu wiring), which is reaching the Cu wiring to fabricate a semiconductor device, followed by a semiconductor device cleaning process. As shown in step S51 of FIG. 15, the via reaching the Cu wiring is formed in an interlayer film on the Cu wiring by dry etching. Thereafter, the semiconductor device is cleaned in the process shown in steps S52 to S55.

As shown in step S52, an organic release process is performed with an amine solvent to remove an etching residue produced in step S51. At this time, under conditions of the organic release process, for example, the temperature is 70° C. and time is 10 minutes. As shown in step S53, the semiconductor device is rinsed with isopropyl alcohol (hereinafter, referred to as IPA) to remove the amine solvent used in step S52. As shown in step S54, the semiconductor device is rinsed with pure water or CO₂ gas-containing water (hereinafter, referred to as CO₂ water) to remove the IPA used in step S53. At this time, rinse conditions are 15 minutes at room temperature. As shown in step S55, the semiconductor device is dried. The semiconductor device is dried by jetting heated N2 gas to the semiconductor device for 10 minutes.

The inventors of the present invention, however, have revealed that washing steps cause problems as described below. In rinsing with the pure water or CO₂ water (hereinafter, generically referred to as pure water) shown in step S54 of FIG. 15, the Cu wiring exposed into the via is eluted into the pure water or CO₂ water. Otherwise, after drying, the Cu wiring in the via is easily oxidized. The present invention has been made in view of such problems and the present invention is a semiconductor device fabricating method including a process for forming a wiring layer on a semiconductor substrate, followed by cleaning, which may prevent elution and oxidation of the wiring layer, and a treating liquid used in this fabricating method.

### SUMMARY OF THE INVENTION

In the method of fabricating the semiconductor device according to the first aspect of the present invention, a wiring layer, an interlayer film and an opening are formed under a plasma atmosphere, and then, the opening is cleaned with a nonaqueous solvent such as IPA. This moves electric charges accumulated onto the interlayer film to the nonaqueous solvent side so as to perform neutralization without eluting the wiring layer. More preferably, before the opening is rinsed with pure water, the opening is cleaned with a treating liquid containing an anticorrosive to form a corrosion-resistant film in the exposed part of the wiring layer. This can prevent the wiring layer from being eluted.

According to the second aspect of the present invention, after an interlayer film or an opening is formed on a semiconductor substrate under a plasma atmosphere, the opening is cleaned with a nonaqueous solvent. Electric charges accumulated onto the interlayer film in the plasma atmosphere are moved to the nonaqueous solvent side, which can be then removed from the interlayer film. When rinsing the semiconductor device with water in the later process, the metal constructing the wiring layer can be prevented from being ionized to be eluted or oxidized. The water is, for example, pure water or CO₂ water. There is also DIW (deionized water) as the pure water.

According to the third aspect of the present invention, after the process for forming the opening, cleaning the opening with a treating liquid containing an anticorrosive is performed. This can form a corrosion-resistant film on the wiring layer exposed in the opening. As a result, when rinsing the semiconductor substrate with water in the later process, the metal constructing the wiring layer can be further prevented from being ionized to be eluted or oxidized. The treating liquid may be composed by adding an anticorrosive to the nonaqueous solvent.

Further, after the process for cleaning the opening with the nonaqueous solvent, the present invention may have a process for cleaning the opening with pure water or carbonated water. This can prevent the nonaqueous solvent from remaining in the opening.

A treating liquid according to the forth aspect of the present invention cleans an opening. After an interlayer film is formed on the wiring layer on a semiconductor substrate, the opening exposing the wiring layer is formed in the interlayer film. The treating liquid contains an anticorrosive.

According to the fifth aspect of the present invention, a treating liquid contains an anticorrosive. An opening is cleaned with the treating liquid to form a corrosion-resistant film on a wiring layer. As a result, when rinsing the semiconductor device with water in the later process, the metal constructing the wiring layer can be prevented from being ionized to be eluted or oxidized. The treating liquid may be composed by adding an anticorrosive to the nonaqueous solvent.

In addition, preferably, the treating liquid has a composition containing benztriazole: 0.5 to 30% by mass, amine: 0.0005 to 1% by mass, water: 0.1 to 5% by mass, and the remainder of isopropyl alcohol and unavoidable impurities, and is alkaline. This can form a more stable corrosion-resistant film on the wiring layer.

### BRIEF DESCRIPTION OF THE DRAWINGS

Features of the illustrative, non-limiting embodiments of the present invention will be more apparent from the following description taken in conjunction with the accompanying drawings, in which:

FIGS. 1A to 1D are schematic plan views showing shapes of wiring layers;

FIG. 2 is a cross-sectional view showing the melting behavior of the wiring layer;

FIG. 3 is a flowchart showing a semiconductor device fabricating method with an organic release liquid according to a embodiment of the present invention;

FIGS. 4A to 4D are cross-sectional views showing the semiconductor device fabricating method according to this embodiment in that process order;

FIGS. 5A to 5D are cross-sectional views showing the semiconductor device fabricating method according to this embodiment in that process order and show the next processes of FIG. 4;

FIGS. 6A and 6B are cross-sectional views showing the semiconductor device fabricating method according to this embodiment in that process order and show the next processes of FIG. 5;

FIGS. 7A to 7C are cross-sectional views showing the semiconductor device fabricating method according to this embodiment in that process order and show the next processes of FIG. 6;

FIGS. 8A to 8C are cross-sectional views showing the semiconductor device fabricating method according to this embodiment in that process order and show the next processes of FIG. 7;

FIGS. 9A to 9C show the SEM observing results of Cu wirings in vias after cleansing in which FIG. 9A is a perspective view showing an observing method, FIG. 9B is a diagram showing the observing result of a Cu wiring of Comparative Example No. 2, and FIG. 9C is a diagram showing the observing result of a Cu wiring of Example No. 3;

FIGS. 10A and 10B are graphs using the position of a sample (wafer) surface to enter the horizontal axis and the potential to enter the vertical axis to show the potential distribution measuring results of the sample in which FIG. 10A shows the potential distribution of the sample before an IPA spray process and FIG. 10B shows the potential distribution of the sample after the IPA spray process;

FIG. 11 is a graph using the pure water rinse time to enter the horizontal axis and the film thickness of BTA films to enter the vertical axis to show pure water rinse time dependence of the film thickness of the BTA films in which a graph (a) shows the measuring result of Example No. 4 and a graph (b) shows the measuring result of Example No. 6; and

FIG. 12 is a flowchart showing a semiconductor device cleaning method with a related art organic release liquid.

### DETAILED DESCRIPTION OF THE EMBODIMENTS

The inventors of the present invention have earnestly conducted experiment and research to solve the foregoing problems and have obtained the following findings about why metal constructing an exposed wiring layer is easily eluted or oxidized when cleaning a semiconductor device with pure water and the like. Specifically, in a process for forming an interlayer film, a wiring layer and a via opening on a semiconductor substrate, methods using plasma, such as sputtering, plasma CVD, dry etching and plasma ashing, are performed. In these processes, the semiconductor substrate and the wiring layer and the interlayer film formed on the semiconductor substrate (hereinafter, referred to as a semiconductor device) are exposed to plasma. This accumulates electric charges onto the interlayer film as an insulating film for charge-up. The electric charges are discharged all at once when the wiring layer and pure water (pure water or CO₂ water) are contacted with each other. Then, the metal forming the wiring layer is ionized an deluted. Otherwise, after drying, the metal forming the wiring layer is easily oxidized. Furthermore, in a semiconductor device cleaning process, an organic release process is performed with an amine solvent. When a native oxide film formed on the surface of the wiring layer, for example, a CuOx film when the wiring layer is formed by Cu, is removed, whereby the metal constructing the wiring layer is eluted more easily.

More detailed description will be made on the semiconductor device including the wiring layer and an interlayer film over the wiring layer. The wiring layer includes a large-area wiring region and a drawing wiring region having a relatively small area drawn from the large-area wiring region. In this case, the larger the large-area wiring region and the higher the number of vias formed in the interlayer film to reach the surface of the large-area wiring region. As the number of the vias becomes large, the metal constructing the wiring layer is more likely to eluted from the via formed in the drawing wiring region. In addition, when the wiring layer is not connected to the semiconductor substrate and is in a floating state, the phenomenon more easily occurs. For example, when the number of the vias formed in the wiring layer in the floating state is below 100, the phenomenon is not significant. On the other habnd, when the number of the vias is above 1000, the phenomenon easily occurs. When the wiring layer exposed in the via is eluted and oxidized, the connection state between the wiring layer and the conductive material buried in the via is deteriorated to lower the reliability of the semiconductor device.

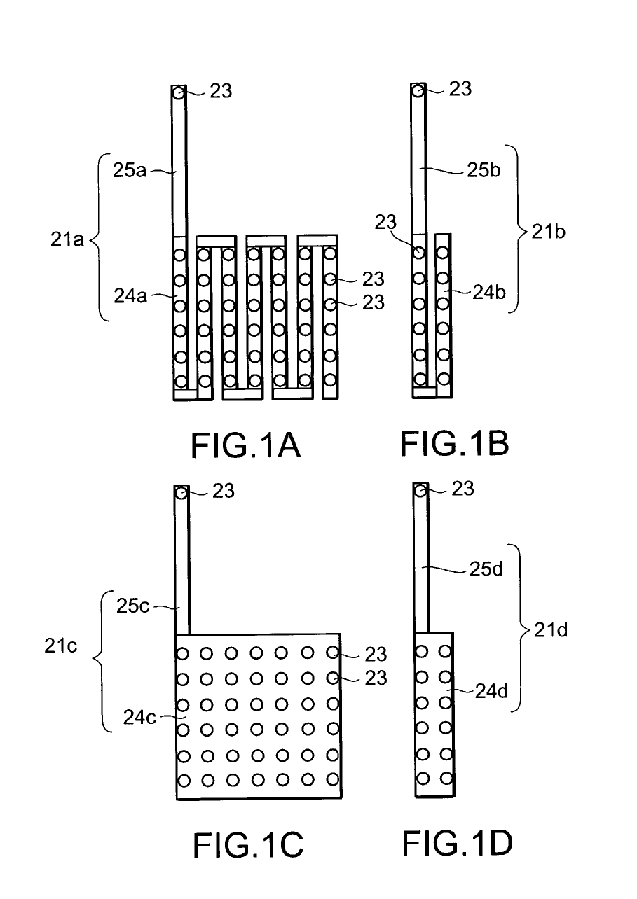

FIGS. 1A to 1D are schematic plan views showing shapes of wiring layers in semiconductor devices. FIGS. 1A to 1B show the wiring layers having a chain-like shape. FIGS. 1C and 1D show the wiring layers having a pad-like shape. As shown in FIG. 1A, a wiring layer 21a made of Cu has a large-area wiring region 24a and a drawing wiring region 25a connected to the large-area wiring region 24a. The area of the large-area wiring region 24a is larger than that of the drawing wiring region 25a. In the semiconductor device as an example, the large-area wiring region 24a is formed with above 100 vias 23, for example, 10000 vias 23, and the large-area wiring region 24a has the wiring layer 21a of a single-line chain shape, and a large number of the vias 23 formed in the interlayer film on the wiring and reaching the wiring layer 21a. The drawing wiring region 25a has a relatively small number of the vias 23, for example, one via 23 formed in the interlayer film and reaching the wiring layer 25a. The number of the vias 23 formed in the drawing wiring region 25a is below 1/100 of the number of the vias 23 formed in the large-area wiring region 24a. The total area of the openings of the vias 23 formed in the drawing wiring region 25a is below 1/100 of the total area of the openings of the vias 23 formed in the large-area wiring region 24a. In the wiring layer 21a shown in FIG. 1A, the number of the vias 23 on the large-area wiring region 24a is so large that the area which is exposed to a plasma atmosphere is also large. Therefore, electric charges are easily accumulated in the large-area wiring region 24a during the process under a plasma atmosphere. The number of the vias 23 formed in the drawing wiring region 25a is smaller than the number of the vias 23 formed in the large-area wiring region 24a. Thus, electric charges are easily discharged concentratedly from the vias 23 formed in the drawing wiring region 25a. The metal (Cu) constructing the wiring layer 21a is easily eluted from the wiring layer 21a exposed into the via 23 formed in the drawing wiring region 25a.

On the contrary, in FIG. 1B, the number of the vias 23 formed in a large-area wiring region 24b is below 100, for example, 20. The number of the vias 23 formed in a drawing wiring region 25b is more than 1/100 of the number of the vias 23 formed in the large-area wiring region 24b. The total area of the openings of the vias 23 formed in the drawing wiring region 25b is larger than 1/100 of the total area of the openings of the vias 23 formed in the large-area wiring region 24b. In a wiring layer 21b shown in FIG. 1B, metal elution in the drawing wiring region 25b is hard to occur.

In a wiring layer 21c shown in FIG. 1C, a large-area wiring region 24c has a pad shape. The area of the large-area wiring region 24c is larger than that of a drawing wiring region 25c. The large-area wiring region 24c is formed with above 100 vias 23, for example, 10000 vias 23. The large-area wiring region 24c is of a plane shape and has the wiring layer 21c and a large number of the vias 23 formed in the interlayer film over the wiring layer 21c and reaching the wiring layer 21c. The drawing wiring region 25c has a relatively small number of the vias 23, for example, one via 23 formed in the interlayer film over the drawing wiring region 25c. The number of the vias 23 formed in the drawing wiring region 25c is below 1/100 of the number of the vias 23 formed in the large-area wiring region 24c. The total area of the openings of the vias 23 formed in the drawing wiring region 25c is below 1/100 of the total area of the openings of the vias 23 formed in the large-area wiring region 24c. Therefore, in the wiring layer 21c shown in FIG. 1C, metal constructing the wiring layer 21c is easily eluted from the via 23 formed in the drawing wiring region 25c.

In a wiring layer 21d shown in FIG. 1D, the number of the vias 23 formed in a large-area wiring region 24d having a pad-like shape is below 100, for example, 20. The number of the vias 23 formed in a drawing wiring region 25d is larger than 1/100 of the number of the vias 23 formed in the large-area wiring region 24d. The total area of the openings of the vias 23 formed in the drawing wiring region 25d is larger than 1/100 of the total area of the openings of the vias 23 formed in the large-area wiring region 24d. Metal elution in the drawing wiring region 25d is hard to occur.

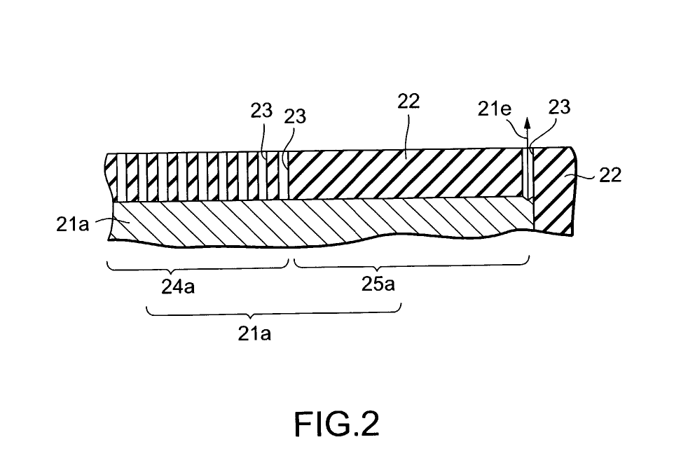

FIG. 2 is a cross-sectional view showing the melting behavior of the wiring layer. The wiring layer shown in FIG. 2 is the same as the wiring layer shown in FIG. 1A. As shown in FIG. 2, a wiring layer 21a made of Cu is provided on a semiconductor substrate, not shown. An interlayer film 22 is provided so as to bury the top and sides of the wiring layer 21a. The wiring layer 21a has a large-area wiring region 24a and a drawing wiring region 25a connected to the large-area wiring region 24a. The number of the vias 23 formed in the large-area wiring region 24a is above 100 times larger than the number of the vias 23 formed in the drawing wiring region 25a. When the semiconductor device is rinsed with pure water (pure water or CO₂ water), the metal Cu constructing the wiring layer 21a is eluted from the via 23 formed in the drawing wiring region 25a. The Cu elution is indicated by arrow 21e.

In the semiconductor device fabricating process according to the present invention, a wiring layer, an interlayer film and an opening are formed under a plasma atmosphere, and then, the opening is cleaned with a nonaqueous solvent such as IPA. This moves electric charges accumulated on to the interlayer film to the nonaqueous solvent side so as to perform neutralization without eluting the wiring layer. More preferably, before the opening is rinsed with pure water, the opening is cleaned with a treating liquid containing an anticorrosive to form a corrosion-resistant film in the exposed part of the wiring layer. This can prevent the wiring layer from being eluted.

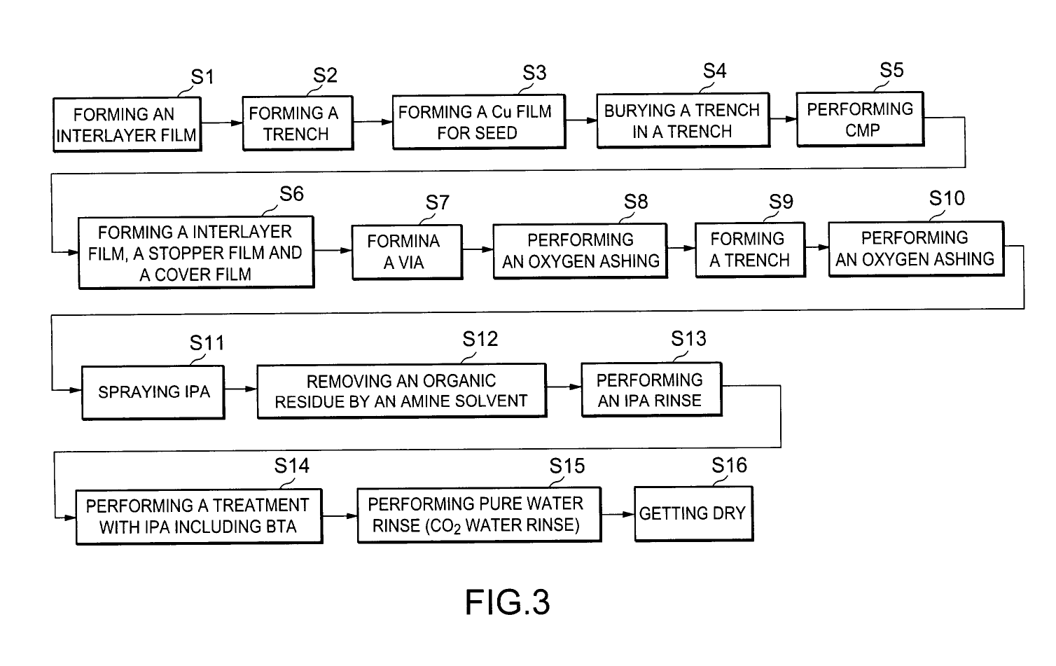

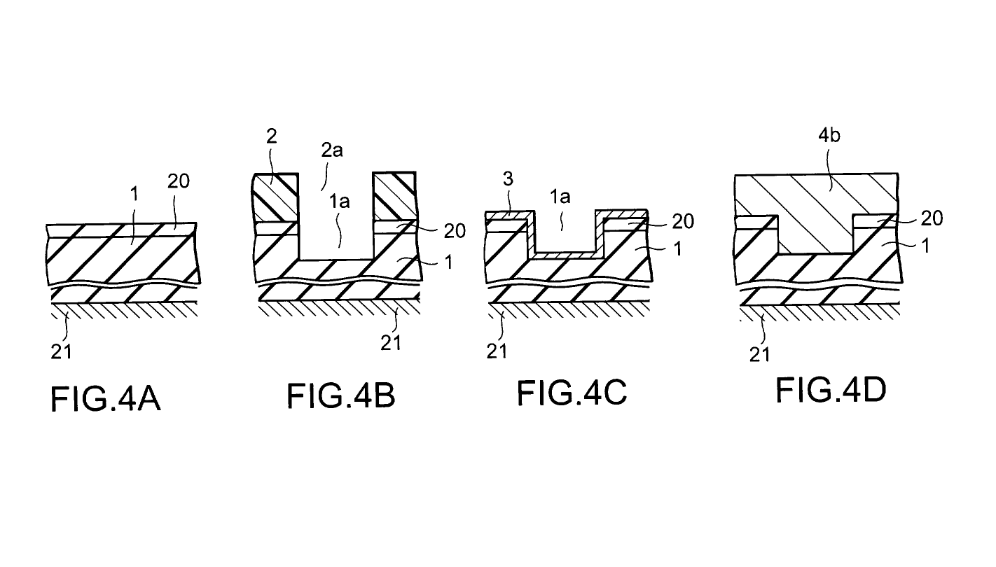

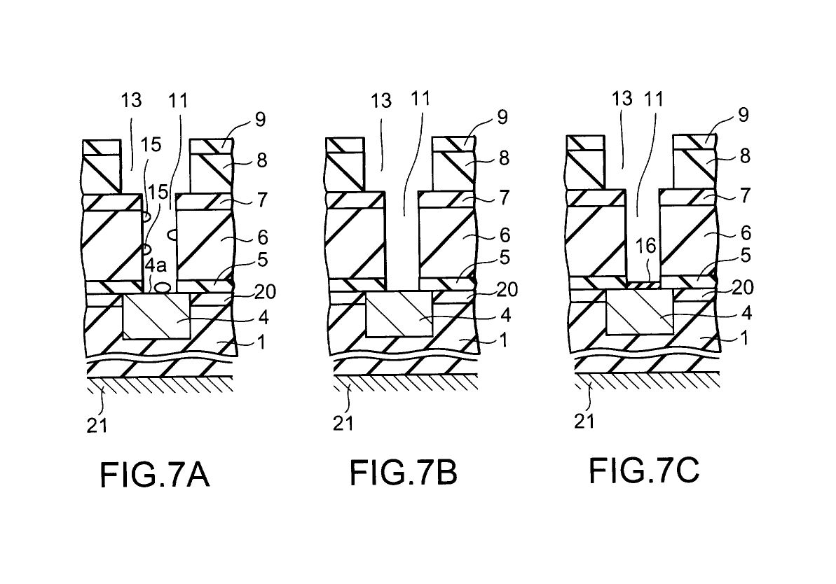

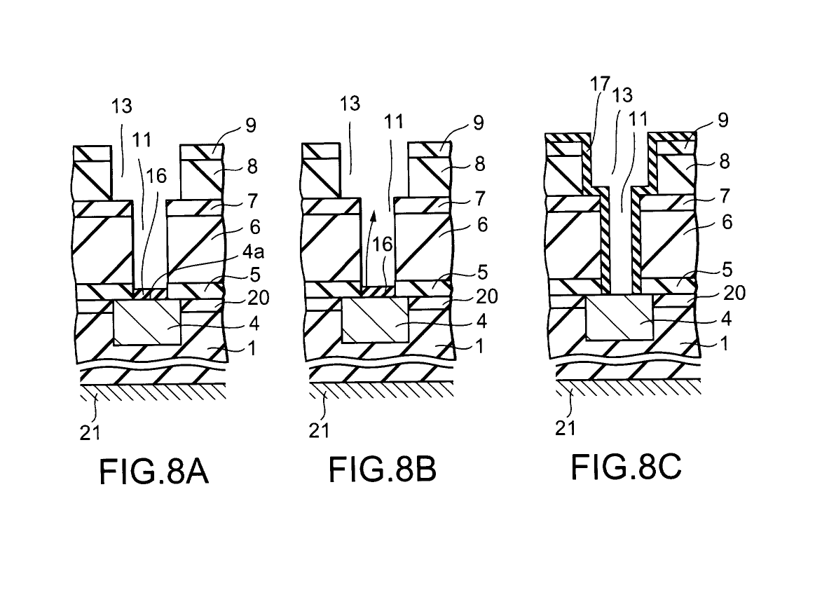

An embodiment of the present invention will be described. FIG. 3 is a flowchart showing a semiconductor device fabricating method with an organic release liquid according to the embodiment. FIGS. 4A to 4D, FIGS. 5A to 5D, FIGS. 6A and 6B, FIGS. 7A to 7C and FIGS. 8A to 8C are cross-sectional views showing the semiconductor device fabricating method according to the embodiment in that process order. FIGS. 4A to 4D, FIGS. 5A to 5D and FIGS. 6A to 6B show the wiring fabricating processes by a dual damascene method. FIGS. 7A to 7C and FIG. 8A show cleaning processes after the wiring fabricating process. FIGS. 8B and 8C show barrier metal forming processes.

As shown in step S1 of FIG. 3 and FIG. 4A, an interlayer film 1 is formed on a semiconductor substrate 21 in a plasma atmosphere. At this time, electric charges may be accumulated onto the interlayer film 1 by plasma. The interlayer film 1 is made of, for example, a low-dielectric-constant film (Low-K film) or an SiO₂ film deposited by a plasma method. The low-dielectric-constant film refers to a film whose relative dielectric constant is less than 4 of the relative dielectric constant of SiO₂. In the embodiment, the relative dielectric constant of the low-dielectric-constant film is 1.0 to 4.0. As the low-dielectric-constant film, there are an inorganic film, an organic film, an organic and inorganic-mixed film, and a porous film thereof. When the interlayer film 1 is the low-dielectric-constant film (Low-K film), a cover film 20 is deposited on the interlayer film 1 by a plasma deposition method or a coating deposition method. The cover film 20 is made of, for example, SiO₂ or SiN. When the interlayer film 1 is not the low-dielectric-constant film but is an SiO₂ film, the cover film 20 is unnecessary.

As shown in step S2 of FIG. 3 and FIG. 4B, a resist 2 having an opening 2a is formed on the cover film 20. The interlayer film 1 is dry etched with the resist 2 as a mask to form a channel la in the interlayer film 1. The channel 1a will be used as a trench for a wiring 4. Electric charges may be accumulated onto the interlayer film 1 by the dry etching. The opening 2a of the resist 2 is provided in a region to form the channel la in the interlayer film 1. Thereafter, the resist 2 is removed.

As shown in step S3 of FIG. 3 and FIG. 4C, a Cu film 3 for seed is deposited on the cover film 20 by an ionizing sputtering method. Also in the process, electric charges may be accumulated onto the interlayer film 1 by plasma. Thereafter, as shown in step S4 of FIG. 3 and FIG. 4D, a Cu film 4b is formed on the Cu film 3 for seed by the plating method.

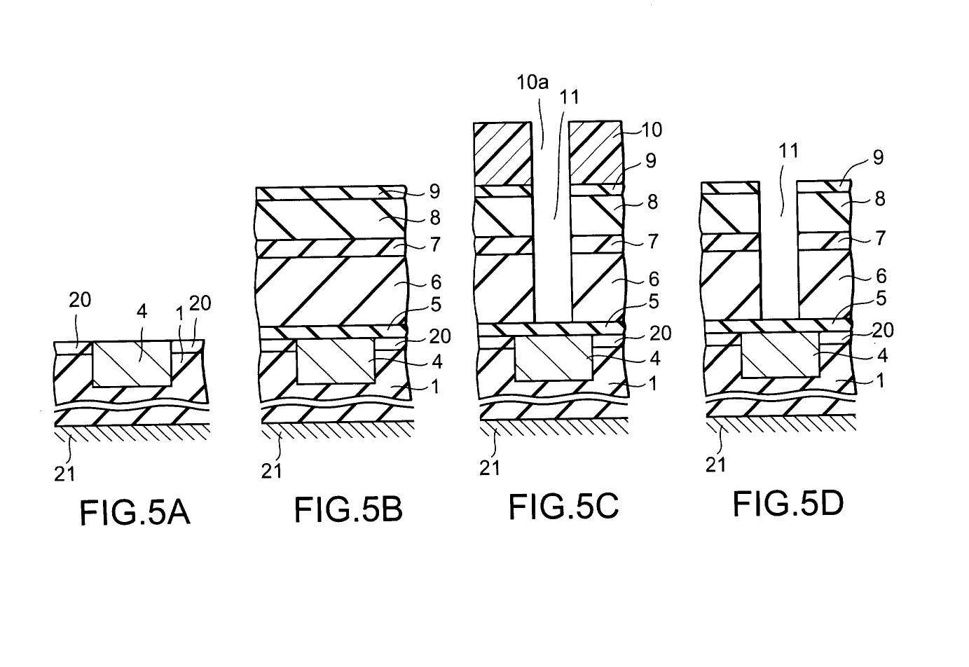

As shown in step S5 of FIG. 3 and FIG. 5A, CMP (Chemical Mechanical Polishing) is conducted to the Cu film 4b to remove the Cu film 4b deposited onto a part other than the inside of the channel 1a. This forms a Cu wiring 4 in the channel la. The wiring may be formed by Ag, or Ag or Cu alloy. As shown in step S6 of FIG. 3 and FIG. 5B, a stopper film 5, an interlayer film 6, a stopper film 7, an interlayer film 8 and a cover film 9 are deposited in that order on the cover film 20 and the Cu wiring 4 by the plasma deposition method or the coating deposition method. At this time, electric charges maybe accumulated onto the interlayer films 1, 6 and 8 by plasma. The stopper films 5 and 7 are made of, for example, SiN, SiCN or SiC. The interlayer films 6 and 8 are made of, for example, the SiO₂ film deposited by the plasma method or the low-dielectric-constant film (Low-K film). When the interlayer film 8 is not the low-dielectric-constant film, the cover film 9 is unnecessary.

As shown in step S7 of FIG. 3 and FIG. 5C, a resist 10 having an opening 10a is formed on the cover film 9. The cover film 9, the interlayer film 8, the stopper film 7 and the interlayer film 6 are dry etched with the resist 10 as a mask to form a via 11. Electric charges may be accumulated on to the interlayer films 1, 6 and 8 by the dry etching. The opening 10a is provided in a region to form the via 11 in the next process. As shown in step S8 of FIG. 3 and FIG. 5D, oxygen ashing is conducted to the resist 10 to remove the resist 10. Electric charges may be accumulated onto the interlayer films 1, 6 and 8 by the oxygen ashing.

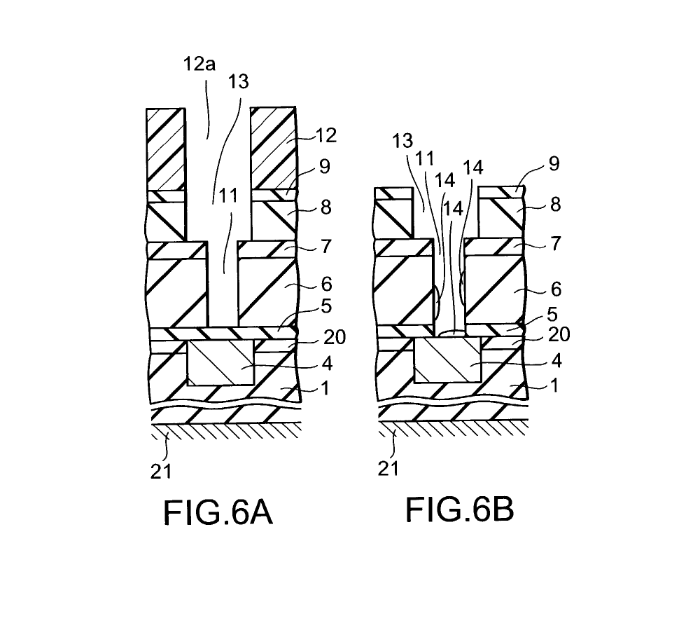

As shown in step S9 of FIG. 3 and FIG. 6A, a resist 12 is formed on the cover film 9. An opening 12a is provided in a region to form a channel 13 of the resist 12 in the next process. The cover film 9 and the interlayer film 8 are dry etched with the resist 12 as a mask to form the channel 13. The channel 13 will be used as a trench for wirings. Electric charges may be accumulated onto the interlayer films 1, 6 and 8 by the dry etching. As shown in step S10 of FIG. 3 and FIG. 6B, after the stopper film 5 in the via 11 is removed, the oxygen ashing is conducted to remove the resist 12. At this time, electric charges may be accumulated onto the interlayer film 6 or 8 by the oxygen ashing. This can obtain a semiconductor device in which the wiring layer 4, interlayer films 6 and 8, via 11 and channels 13 are formed on the semiconductor substrate. An etching residue 14 (depot) remains in the via 11 and the channel 13.

Thereafter, in the process of steps S11 to S16, the semiconductor device formed in steps S1 to S15 is cleaned. As shown in step S11, IPA (isopropyl alcohol) is sprayed to the semiconductor device at room temperature for one minute to clean the semiconductor device. This moves part of electric charges accumulated onto the interlayer films 1, 6 and 8 to the IPA side so as to be removed. Since the IPA is a nonaqueous solvent, Cu constructing the Cu wiring 4 can be prevented from being ionized and eluted.

As shown in step S12 of FIG. 3 and FIG. 7A, an organic release process is conducted with an amine solvent to remove an etching residue 14 (see FIG. 6B). Under conditions of the organic release process, for example, the temperature is 70° C. and time is 10 minutes. At this time, in the via 11 and the channel 13, the etching residue 14 is removed and part of an amine 15 remains. As shown in step S13 of FIG. 3 and FIG. 7B, the semiconductor device is rinsed with the IPA to remove the remaining amine 15.

As shown in step S14 of FIG. 3 and FIG. 7C, a treating liquid prepared by adding, to the IPA, 5% by mass of benztriazole (BTA), 0.01% by mass of amine, and 1% by mass of water is sprayed to the semiconductor device. The treating liquid is alkalescent and has a pH, for example, below 8.5. This forms a BTA film 16 on an exposed part 4a of the Cu wiring 4 in the via 11. In a word, the treating liquid comprising the nonaqueous solvent and the anticorrosive is supplied to the semiconductor device.

As shown in step S15 of FIG. 3 and FIG. 8A, the semiconductor device is rinsed with pure water or CO₂ water. The rinse conditions are 15 minutes at room temperature. At this time, since the BTA film 16 exists on the exposed part 4a of the Cu wiring 4 in the via 11, the Cu constructing the Cu wiring 4 can be prevented from being eluted or oxidized. The rinse removes the treating liquid and the BTA film 16 remains. As shown in step S16 of FIG. 3, the semiconductor device is dried. The semiconductor device is dried by jetting heated N2 gas for 10 minutes. The step S15 may be omitted. If the step 15 is omitted, the elution or oxidization of wiring may be prevented effictively.

After completing cleaning of the semiconductor device, as described above, thereafter, as shown in FIGS. 8B and 8C, a barrier metal is formed. The barrier metal is formed before forming the Cu wiring in the via 11 and the channel 13 by the plating method. As shown in FIG. 8B, as a pretreatment of the barrier metal deposition, preheating is conducted in a vacuum at the temperatures of above 200° C. for 20 to 30 seconds to perform RF sputtering by Ar gas or H2 gas, thereby removing the BTA film 16. As shown in FIG. 8C, a barrier metal 17 is deposited on the wiring layer 4 and in the inner surfaces of the via 11 and the channel 13 by a sputtering method or a CVD method. The inner surfaces of the via 11 and the channel 13 are coated by the barrier metal 17. The barrier metal 17 is made of TaN, Ta or TiN. Thereafter, a metal material such as Cu is buried in the via 11 and the channel 13 by the plating method or the CVD method to form a wiring.

After drying the semiconductor device shown in step S16, the BTA film 16 remains in the via 11. The BTA film 16 is removed by the preheating and RF sputtering shown in FIG. 8B. There arises no problem in the barrier metal 17 formation shown in FIG. 8C. The RF sputtering shown in FIG. 8B and the barrier metal 17 formation shown in FIG. 8C can be conducted in the same sputtering system. This performs RF sputtering in the chamber of the sputtering system, and then, the barrier metal 17 can be formed continuously without breaking the vacuum of the chamber.

As described above, in the embodiment, the semiconductor device is cleaned with the IPA as a nonaqueous solvent in step S11. Electric charges accumulated on to the interlayer film can be discharged without eluting the Cu constructing the Cu wiring 4. When rinsing the semiconductor device with pure water or CO 2 water in step S15, the Cu constructing the Cu wiring 4 can thus be prevented from being eluted. The treating liquid is sprayed to the semiconductor device in step S14 to form the BTA film 16 on the exposed part 4a of the Cu wiring 4 in the via 11. In the semiconductor device rinsing process with pure water or CO₂ water in step S15, the Cu constructing the Cu wiring 4 can thus be prevented from being eluted. The exposed part 4a of the Cu wiring 4 after drying can be also prevented from being oxidized. This can increase time during which the cleaned semiconductor device can be maintained in a normal state, that is, allowable time. Time from the cleaning process to the next process can be increased to facilitate control of the fabricating process.

The embodiment shows an example in which the semiconductor device is cleaned with the IPA in step 11 to form the BTA film 16 on the exposed part 4a of the Cu wiring 4 in step S14. In the present invention, only cleaning with the IPA is conducted to prevent to a considerable degree the Cu from being eluted in the later rinsing process with pure water or CO₂ water. As shown in the embodiment, both the cleaning with the IPA and the BTA film formation are performed to prevent the Cu elution in the above-described rinsing process with pure water more effectively. As the nonaqueous solvent, in place of IPA, there may be used isobutyl alcohol, isopentyl alcohol, ethyl ether, ethyleneglycolmonoethylether, propanol, 1-butanol, 2-butanol, methanol, methyl isobutyl ketone, or methyl ethyl ketone.

Also in the embodiment, the treating liquid has a composition having 5% by mass of BTA, 0.01% by mass of amine, 1% by mass of water, and the remainder of the IPA. The treating liquid composition in the present invention is not limited to this. As the anticorrosive, in place of BTA, there may be used 1,2,3-tolyltriazole, 1,2,4-tolyltriazole, carboxybenztriazole, 1-hydroxybenztriazole, nitrobenztriazole, 5-methyl-1H benztriazole, dihydroxypropylbenztriazole, a ureic anticorrosive, or a purine compound anticorrosive. As the nonaqueous solvent, in place of IPA, there may be used isobutyl alcohol, isopentyl alcohol, ethyl ether, ethylene glycol monoethyl ether, propanol, 1-butanol, 2-butanol, methanol, methyl isobutyl ketone, or methyl ethyl ketone. As the amine, there may be used 1-amino-2-propanol, 2-amino-1-propanol, 3-amino-1-propanol, 2-methyl amino ethanol, 2-amino-2-amino-2-methy-1-propanol, 2-diethylaminoethanol, monoethanol amine, diethanol amine, triethanol amine, 2-(2-aminoethoxy)ethanol, 2-(2-aminoethylamino)ethanol, 2-(diethylamino)ethanol, 2-di(methylamine)ethanol, choline, morpholine, diethylenetriamine, or triethylenetetramine, or a mixture of those.

When the BTA is used as the anticorrosive and the IPA is used as the nonaqueous solvent, preferably, the BTA is 0.5 to 30% by mass, amine is 0.0005 to 1% by mass, and water is 0.1 to 5% by mass. Water and amine in the range are added to the treating liquid to make the treating liquid alkalescent. This can stabilize a bonding of BTA and Cu and the BTA film.

Effects of the examples of the present invention will be specifically described as compared with a comparative example deviated from claims. A sample fabricating method will be described first. An interlayer film is formed on a semiconductor substrate to form a Cu wiring in the interlayer film by sputtering and plasma CVD, forming an SiN film on the interlayer film and the Cu wiring. SiO₂ is deposited on the SiN film by the plasma method to form an interlayer film, forming a via by dry etching in a position matched with the Cu wiring in the interlayer film to provide a sample. Seven samples are fabricated.

The samples are cleaned in accordance with the processes shown in Table 1. The processing methods in the respective processes are the same as the methods shown in an embodiment of the present invention. “IPA1” shown in Table 1 indicates an IPA spray process shown in step S11 of FIG. 3. “Organic release” indicates an organic release process with an amine solvent shown in step S12 of FIG. 3. “IPA2” indicates an IPA rinse shown in step S13 of FIG. 3. “BTA aqueous solution” indicates a BTA film forming process with a BTA-added IPA treating liquid (aqueous solution) shown in step S14 of FIG. 3. “BTA-added IPA” indicates a BTA-added IPA process” in which water and amine are not added to the treating liquid and a treating liquid not prepared to be alkalescent is used. “Pure water” and “CO₂ water” indicate pure water rinse and CO₂ water rinse shown in S15 of FIG. 3, respectively. “Drying” indicates a drying process shown in S16 of FIG. 3.

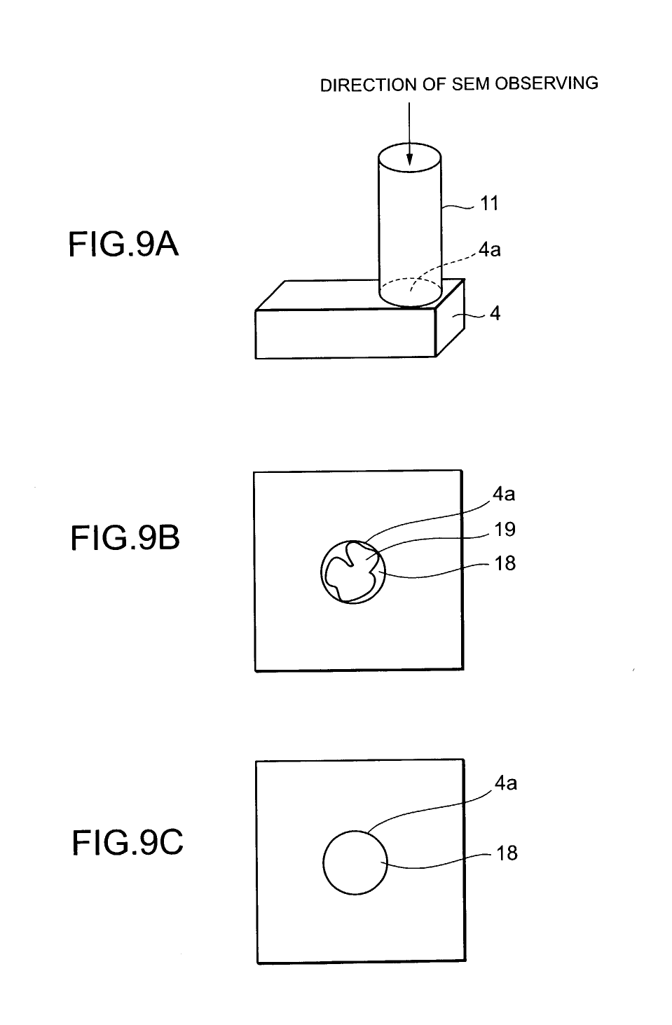

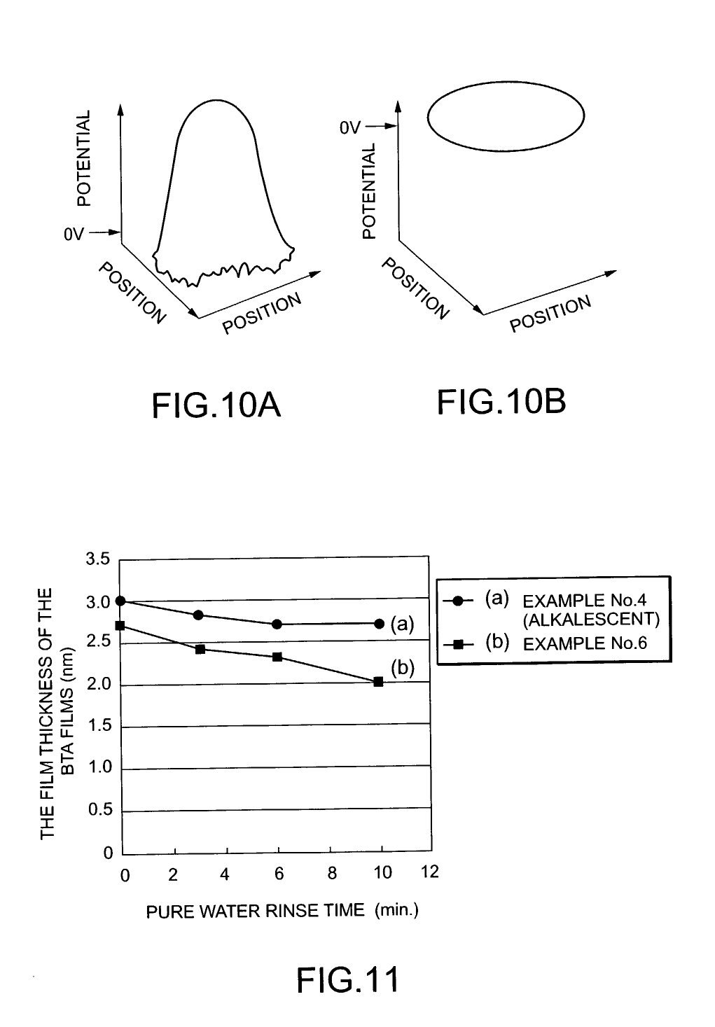

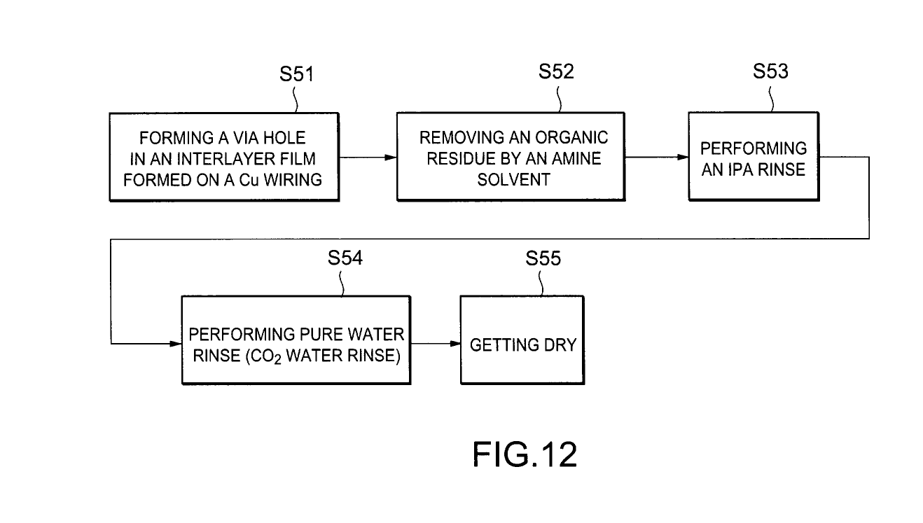

For the samples after cleaned in this manner, the presence or absence of elution of the Cu wiring in the via is evaluated by observing the exposed part of the Cu wiring via the via by an SEM (scanning electron microscope). The evaluating results are shown in Table 1. In Table 1, the sample in which elution is observed is evaluated to be failure (X) the sample in which elution is hardly observed is evaluated to be good (◯), and the sample in which elution is not observed at all is evaluated to be very good (⊚). In addition, part of the SEM observing results is shown in FIGS. 9A to 9C. Further, the potential distribution of the sample before and after the IPA spray process is measured. The measuring results are shown in FIGS. 10A and 10B. Furthermore, for Nos. 4 and 6 shown in Table 1, pure water rinse time dependence of the film thickness of the corrosion-resistant films (BTA films) formed on the Cu wirings is inspected by the BTA-added IPA process. The inspecting results are shown in FIG. 11.

TABLE 1

| No. | Process | Elution |
|---|---|---|
| Example 1 | IPA1 - Organic release - IPA2 - CO₂ water - Drying | ◯ |
| Comparative Example 2 | Organic release - IPA2 - BTA aqueous solution - CO₂ water - Drying | X |
| Example 3 | IPA1 - Organic release - IPA2 - BTA aqueous solution - CO₂ water - Drying | ◯ |
| Example 4 | IPA1 - Organic release - IPA2 - BTA aqueous solution - Pure water - Drying | ◯ |
| Example 5 | IPA1 - Organic release - IPA2 - BTA-added IPA - CO₂ water - Drying | ⊚ |
| Example 6 | IPA1 - Organic release - IPA2 - BTA-added IPA - Pure water - Drying | ⊚ |
| Example 7 | IPA1 - Organic release - IPA2 - Drying | ⊚ |

Nos. 1, 3 to 7 shown in Table 1 are examples of the present invention. For Examples Nos. 1, 3 to 7, the IPA spray process (IPA1) before the organic release process is performed to the samples. Elution of the Cu wirings is hardly observed or is not observed at all.

In particular, in Examples Nos. 5 and 6, the BTA-added IPA process is performed before the CO₂ water rinse (CO₂ water) or pure water rinse (pure water). Since water is not added in the treating liquid, Cu elution is not observed at all. In Example No. 7, since CO₂ water rinse and pure water rinse are not performed, Cu elution is not observed at all.

On the contrary, No. 2 shown in Table 1 is a comparative example. In Comparative Example 2, a Cu wiring and a via are formed on a semiconductor substrate, and then, the organic release process is performed without conducting the IPA spray process. Thereafter, the CO₂ water rinse is performed. Neutralization of the sample during the CO₂ water rinse is not enough so that the Cu wiring is eluted.

FIGS. 9A to 9C show the SEM observing results of the Cu wirings in the vias after cleansing. FIG. 9A is a perspective view showing an observing method. FIG. 9B is a diagram showing the observing result of the Cu wiring of Comparative Example No. 2. FIG. 9C is a diagram showing the observing result of the Cu wiring of Example No. 3. As shown in FIG. 9A, the exposed part 4a of the Cu wiring 4 is observed from the top by the SEM via the via 11 formed on the Cu wiring 4. As a result, as shown in FIG. 9B, in Comparative Example No. 2, a noncorrosive part 18 is observed in a peripheral part of the exposed part 4a of the Cu wiring 4. A corrosive part 19 is observed in the center part thereof to find Cu elution. As shown in FIG. 9C, in Example No. 3, no corrosive part is observed in the exposed part 4a of the Cu wiring 4 so that the entire exposed part 4a is the noncorrosive part 18.

FIGS. 10A and 10B are graphs using the position of the sample (wafer) surface to enter the horizontal axis and the potential to enter the vertical axis to show the potential distribution measuring results of the sample. FIG. 10A shows the potential distribution of the sample before an IPA spray process. FIG. 10B shows the potential distribution of the sample after the IPA spray process. As shown in FIGS. 10A and 10B, the sample before the IPA spray process becomes positively charged, in particular, the electrostatic charge of the center part of the sample is large, and the sample after the IPA spray process is neutralized.

FIG. 11 is a graph using the pure water rinse time to enter the horizontal axis and the film thickness of the BTA films to enter the vertical axis to show pure water rinse time dependence of the film thickness of the BTA films. A graph (a) shows the measuring result of Example No. 4, that is, the case of using a treating liquid prepared to be alkalescent by adding amine to perform the BTA-added IPA process. A graph (b) shows the measuring result of Example No. 6, that is, the case of using a treating liquid not prepared to be alkalescent without adding amine to perform the BTA-added IPA process. As shown in FIG. 11, in the case of using, as the treating liquid, the BTA-added IPA treating liquid prepared to be alkalescent by adding amine, as compared with in the case of using the BTA-added IPA treating liquid to which no amine is added, the BTA film immediately after being formed is thick and the film thickness can be maintained relatively stably when giving pure water rinse. This is because the treating liquid is prepared to be alkalescent to further stabilize the bonding of BTA and Cu.

As described above in detail, according to the present invention, a semiconductor device fabricating method including a process for forming a wiring layer on a semiconductor substrate, followed by cleaning, can prevent elution and oxidation of the wiring layer.

The present invention is not limited to the above embodiments, and it is contemplated that numerous modifications may be made without departing from the spirit and scope of the invention. The method of fabricating a semiconductor device, as described above with reference to the figures, is a merely an exemplary embodiment of the invention, and the scope of the invention is not limited to these particular embodiments. For example, the specific layers and materials that are used to create the semiconductor devices of the non-limiting embodiments are merely examples, and one skilled in the art will readily know that the present invention can be applied to devices containing different layers and materials. Accordingly, other structural configurations may be used, without departing from the sprit and scope of the invention as defined in the claims.

It is noted that Applicants intent in the present specification and claims is to encompass e equivalents of all claim elements, even if amended during prosecution.

What is claimed is:

1. A method of fabricating a semiconductor device formed on a semiconductor wafer, comprising:
providing a wiring layer exposed into a via hole formed in an interlayer film covering said wiring layer;
cleaning said wiring layer with an organic residue; and
supplying a nonaqueous solvent to said interlayer film before said cleaning said wiring.

2. The method as claimed in claim 1, wherein at least one of said via hole and said interlayer film is treated in a plasma atmosphere before said supplying a nonaqueous solvent.

3. The method as claimed in claim 2, further comprising:
supplying a treating liquid comprising an anticorrosive to said via hole.

4. The method as claimed in claim 3, wherein said treating liquid comprising a nonaqueous solvent.

5. The method as claimed in claim 4, further comprising:
cleaning said semiconductor device with a nonaqueous solvent after cleaning said wiring layer with an organic residue.

6. The method as claimed in claim 5, further comprising:
drying out said semiconductor device after said cleaning said semiconductor device with said nonaqueous solvent.

7. The method as claimed in claim 1, wherein said providing said wiring layer further comprises:
forming a resist pattern on said interlayer film;
etching said interlayer film selectively with using said resist pattern as a mask; and
performing an ashing to remove said resist pattern.

8. The method as claimed in claim 1, wherein said wiring layer is made of at least one which is selected from a group comprising a copper, a silver, a copper alloy and a silver alloy.

9. The method as claimed in claim 1, wherein said nonaqueous solvent is an alcohol.

10. The method as claimed in claim 9, wherein said nonaqueous solvent is one which is selected from a group comprising an isopropyl alcohol, an isobutyl alcohol, an isopentyl alcohol, an ethyl ether, an ethylene glycol monoethyl ether, a propanol, a 1-butanol, a 2-butanol, a methanol, a methyl isobutyl ketone, and a methyl ethyl ketone, or a mixture of more than two which are selected from said group.

11. The method as claimed in claim 3, wherein said anticorrosive is one which is selected from a group comprising a benztriazole, a 1,2,3-tolyltriazole, a 1,2,4-tolyltriazole, a carboxybenztriazole, a 1-hydroxybenztriazole, a nitrobenztriazole, a 5-methyl-1H-benztriazole, a dihydroxypropylbenztrlazole, a ureic anticorrosive, and a purine compound anticorrosive, or a mixture of more than two which are selected from said group.

12. The method as claimed in claim 3, wherein said treating liquid comprises an isopropyl alcohol, a benztriazole which is 0.5 to 30% by mass, an amine which is 0.0005 to 1% by mass, and a water which is 0.1 to 5% by mass, and said treating liquid is an alkalescent.

13. The method as claimed in claim 12, wherein said amine is one which is selected from a group comprising a 1-amino-2-propanol, a 2-amino-1-propanol, a 3-amino-1-propanol, a 2-methyl amino ethanol, a 2-amino-2-amino-2-methy-1-propanol, a 2-diethylaminoethanol, a monoethanolamine, a diethanolamine, a triethanol amine, a 2-(2-aminoethoxy)ethanol, a 2-(2-aminoethylamino)ethanol, a 2-(diethylamino)ethanol, a 2-di(methylamine)ethanol, a choline, a morpholine, a diethylenetriamine, and a triethylenetetramine, or a mixture of more than two which are selected from said group.

14. The method as claimed in claim 1, wherein said wiring layer is isolated from said semiconductor wafer, and said wiring layer comprises a large-area wiring region and a drawing wiring region, and an exposed area in said via hole reaching said large-area wiring region is larger than an exposed area in said via hole reaching said drawn wiring region.

15. The method as claimed in claim 14, wherein said exposed area in said via hole reaching said large-area wiring region is almost 100 times as large as said exposed area in said via hole reaching said drawing wiring region.

16. The method as claimed in claim 15, wherein a number of said via hole reaching said large-area wiring region is more than 1000, and a number of said via hole reaching said large-area wiring region is more than 100 times as much as a number of said via hole reaching said drawing wiring region.

17. A treating liquid for cleaning a via hole in an interlayer film covering a wiring layer formed on a semiconductor wafer, comprising an anticorrosive.

18. The treating liquid as claimed in claim 17, further comprising a nonaqueous solvent.

19. The treating liquid as claimed in claim 18, wherein said nonaqueous solvent is an alcohol.

20. The treating liquid as claimed in claim 18, wherein said nonaqueous solvent is one which is selected from a group comprising an isopropyl alcohol, an isobutyl alcohol, an isopentyl alcohol, an ethyl ether, an ethylene glycol monoethyl ether, a propanol, a 1-butanol, a 2-butanol, a methanol, a methyl isobutyl ketone, and a methyl ethyl ketone, or a mixture of more than two which are selected from said group.

21. The treating liquid as claimed in claim 17, wherein said anticorrosive is one which is selected from a group comprising a benztriazole, a 1,2,3-tolyltriazole, a 1,2,4-tolyltriazole, a carboxybenztriazole, a 1-hydroxybenztriazole, a nitrobenztriazole, a 5-methyl-1H-benztriazole, a dihydroxypropylbenztriazole, a ureic anticorrosive, and a purine compound anticorrosive, or a mixture of more than two which are selected from said group.

22. The treating liquid as claimed in claim 17, comprising:
an isopropyl alcohol;
a benztriazole which is 0.5 to 30% by mass;
an amine which is 0.0005 to 1% by mass; and
a water which is 0.1 to 5% by mass, and
wherein said treating liquid is an alkalescent.

23. The treating liquid as claimed in claim 22, wherein said amine is one which is selected from a group comprising a 1-amino-2-propanol, a 2-amino-1-propanol, a 3-amino-1-propanol, a 2-methyl amino ethanol, a 2-amino-2-amino-2-methy-1-propanol, a 2-diethylaminoethanol, a monoethanol amine, a diethanol amine, a triethanol amine, a 2-(2-aminoethoxy)ethanol, a 2-(2-aminoethylamino)ethanol, a 2-(diethylamino)ethanol, a 2-di(methylamine)ethanol, a choline, a morpholine, a diethylenetriamine, and a triethylenetetramine, or a mixture of more than two which are selected from said group.
